(19) United States
(12) Patent Application Publication
(10) Pub. No.: US 2013/0017671 A1
(43) Pub. Date: Jan. 17, 2013

(54) METHOD FOR MANUFACTURING SEMICONDUCTOR DEVICE

(71) Applicants: Hiroyuki KITABAYASHI, Osaka-shi (JP); Taku HORII, Osaka-shi (JP)

(72) Inventors: Hiroyuki KITABAYASHI, Osaka-shi (JP); Taku HORII, Osaka-shi (JP)

(73) Assignee: Sumitomo Electric Industries, Ltd., Osaka-shi (JP)

(21) Appl. No.: 13/547,547

(22) Filed: Jul. 12, 2012

Related U.S. Application Data
(60) Provisional application No. 61/508,303, filed on Jul. 15, 2011.

(30) Foreign Application Priority Data
Jul. 15, 2011 (JP) 2011-156226

(51) Int. Cl. H01L 21/78

(52) U.S. Cl. 438/464; 257/E21.599

(57) ABSTRACT

A method for manufacturing a semiconductor device includes the steps of: preparing a substrate having a region that at least includes one main surface thereof and that is made of single-crystal silicon carbide; forming an active layer on the one main surface; grinding a region including the other main surface of the substrate opposite to the one main surface; removing a damaged layer formed in the step of grinding the region including the other main surface; and forming a backside electrode in contact with the main surface exposed by the removal of the damaged layer. The one main surface has an off angle of not less than 50° and not more than 65° relative to a {0001} plane.

### BACKGROUND OF THE INVENTION

1. Field of the Invention

The present invention relates to a method for manufacturing a semiconductor device, more particularly, a method for manufacturing a silicon carbide semiconductor device allowing for reduced on-resistance.

2. Description of the Background Art

In recent years, in order to achieve high breakdown voltage, low loss, and utilization of semiconductor devices under a high temperature environment, silicon carbide (SiC) has begun to be adopted as a material for a semiconductor device. Silicon carbide is a wide band gap semiconductor having a band gap larger than that of silicon, which has been conventionally widely used as a material for semiconductor devices, and characteristically has a large dielectric breakdown voltage. Hence, by adopting silicon carbide as a material for a semiconductor device, the semiconductor device can have a high breakdown voltage and reduced on-resistance, simultaneously. Further, the semiconductor device thus adopting silicon carbide as its material has characteristics less deteriorated even under a high temperature environment than those of a semiconductor device adopting silicon as its material, advantageously.

A proposed method for manufacturing such a semiconductor device employing silicon carbide as its material is to reduce the thickness of the substrate by grinding the backside surface (main surface opposite to an active layer) of the silicon carbide substrate, and then form an electrode on the main surface thus grinded (for example, see U.S. Pat. No. 7,547,578 (Patent Literature 1)).

However, even when the thickness of the substrate is reduced, a contact resistance between the substrate and the electrode may become large, with the result that the on-resistance of the semiconductor device cannot be reduced sufficiently.

### SUMMARY OF THE INVENTION

The present invention has been made to solve such a problem, and has its object to provide a method for manufacturing a semiconductor device, which allows for sufficient reduction of on-resistance.

A method for manufacturing a semiconductor device in the present invention includes the steps of: preparing a substrate having a region that at least includes one main surface thereof and that is made of single-crystal silicon carbide; forming an active layer on the one main surface; grinding a region including the other main surface of the substrate opposite to the one main surface; removing a damaged layer formed in the step of grinding the region including the other main surface; and forming a backside electrode in contact with the main surface exposed by the removal of the damaged layer. The one main surface has an off angle of not less than 50° and not more than 65° relative to a {0001 } plane.

The present inventor has obtained the following findings and arrived at the present invention as a result of detailed study on cause and countermeasure of the above-described problem, i.e., the increase of the contact resistance between the substrate and the electrode.

Specifically, when the substrate is grinded to have a small thickness, the main surface thus grinded has defects resulting from the processing. The defects tend to be formed and expand along the {0001} plane of silicon carbide. Accordingly, when using a substrate having a main surface close to the { 0001 } plane, specifically, a general substrate having a main surface having an off angle of approximately 8° or smaller relative to the {0001} plane, the defects are formed only in a very thin region in the vicinity of the surface exposed by the grinding. As a result, the defects less affect the contact resistance between the electrode and the substrate.

On the other hand, when using a substrate having a large off angle relative to the {0001} plane, specifically, a substrate having an off angle of not less than 50° and not more than 65° relative to the {0001 } plane, advantageous effects may be obtained such as improved channel mobility and reduced leakage current in the semiconductor device. If such a substrate having an off angle of not less than 50° and not more than 65° relative to the {0001} plane is used in order to obtain these effects, the defects are formed and expand along the {0001} plane and accordingly exist in a region deeper from the surface exposed by the grinding. Accordingly, if an electrode is formed in contact with such a surface, a contact resistance between the substrate and the electrode becomes large, with the result that the on-resistance of the semiconductor device cannot be reduced sufficiently, disadvantageously.

To address this, in the method for manufacturing the semiconductor device in the present invention, the other main surface opposite to the one main surface having an off angle of not less than 50° and not more than 65° relative to the {0001} plane is grinded and thereafter the resulting damaged layer is removed before forming the backside electrode. Accordingly, even when the defects are formed up to a deep region, the region including the defects is removed before forming the backside electrode. Accordingly, a contact resistance between the substrate and the backside electrode becomes small, thereby sufficiently reducing the on-resistance of the semiconductor device. Thus, according to the method for manufacturing the semiconductor device in the present invention, there can be provided a method for manufacturing a semiconductor device allowing for sufficient reduction of on-resistance.

Here, the step of removing the damaged layer is intended to indicate a step of removing a surface portion mainly damaged chemically rather than physically, i.e., a step of removing the surface portion by means of dry etching such as RIE (Reactive Ion Etching) or wet etching; or is intended to indicate a step of removing the surface portion physically by means of dry polishing or the like using a metal oxide, etc., without using abrasive grains, etc., having a hardness equal to or greater than that of silicon carbide, such as diamond or CBN (Cubic Boron Nitride), for example.

In the method for manufacturing the semiconductor device, in the step of removing the damaged layer, the damaged layer may be removed by dry polishing. The dry polishing, which can remove the surface portion while restraining new damage on the substrate, is suitable for the method for removing the damaged layer. Further, the dry polishing is readily performed in a continuous manner from the preceding grinding step, thereby restraining the manufacturing process from being complicated due to the removal of the damaged layer. This contributes to reduction of manufacturing cost.

In the method for manufacturing the semiconductor device, in the step of removing the damaged layer, the damaged layer may be removed by dry etching. The dry etching, which can remove the surface portion while restraining new damage on the substrate, is suitable for the method for removing the damaged layer.

In the method for manufacturing the semiconductor device, in the step of preparing the substrate, a combined wafer may be prepared in which a plurality of SiC substrates each made of single-crystal silicon carbide are arranged side by side when viewed in a plan view, the plurality of SiC substrates having first main surfaces that serve as the one main surface and having second main surfaces opposite to the first main surfaces and connected to each other by a supporting layer, and in the step of grinding the region including the other main surface, the supporting layer may be removed.

It is difficult for a substrate made of single-crystal silicon carbide to keep its high quality and have a large diameter. To address this, a plurality of high-quality SiC substrates each having a small diameter and obtained from a silicon carbide single-crystal are arranged side by side when viewed in a plan view and they are connected to one another using a supporting layer having a large diameter, thereby obtaining a combined wafer that is excellent in crystallinity and can be handled as a silicon carbide substrate having a large diameter. Use of such a combined wafer having the large diameter allows for efficient manufacturing of semiconductor devices. An exemplary, usable supporting layer is a layer constituted by a silicon carbide substrate having a quality such as crystallinity lower than that of each of the above-described SiC substrates, or a layer made of a metal. By removing the supporting layer during the manufacturing process, the supporting layer made of low-quality silicon carbide or the like can be restrained from adversely affecting characteristics of the semiconductor device to be finally obtained.

The method for manufacturing the semiconductor device may further include the steps of: forming a front-side electrode on the active layer; adhering an adhesive tape at a side thereof on which the front-side electrode is formed, so as to support the plurality of SiC substrates using the adhesive tape with the plurality of SiC substrates being arranged side by side when viewed in a plan view. In the step of grinding the region including the other main surface, the supporting layer may be removed while using the adhesive tape to support the plurality of SiC substrates with the plurality of SiC substrates being arranged side by side when viewed in a plan view. The method for manufacturing the semiconductor device may further include the steps of: adhering an adhesive tape at a side thereof on which the backside electrode is formed, and removing the adhesive tape at the side thereof on which the front-side electrode is formed, so as to support the plurality of SiC substrates using the adhesive tape with the plurality of SiC substrates being arranged side by side when viewed in a plan view; and obtaining a plurality of semiconductor devices by cutting the SiC substrates in a thickness direction thereof with the plurality of SiC substrates being supported by side by side when viewed in a plan view using the adhesive tape at the side thereof on which the backside electrode is formed.

If the supporting layer connecting the plurality of SiC substrates to one another is removed without any countermeasure as described above, the plurality of SiC substrates are separated from each other, thus hindering highly efficient manufacturing of semiconductor devices. To address this, the supporting layer is removed while using the adhesive tape to support the plurality of SiC substrates such that they are arranged side by side when viewed in a plan view. The adhesive tape supports the plurality of SiC substrates such that they are arranged side by side when viewed in a plan view, until the step of obtaining the plurality of semiconductor devices by cutting the SiC substrates in the thickness direction. In this way, the plurality of SiC substrates are avoided from being separated from one another, thus achieving efficient manufacturing of semiconductor devices.

In the method for manufacturing the semiconductor device, the step of forming the backside electrode may include the steps of: forming a metal layer in contact with the main surface exposed by the removal of the damaged layer; and heating the metal layer. Accordingly, the backside electrode capable of forming ohmic contact with the substrate can be readily formed.

In the method for manufacturing the semiconductor device, in the step of heating the metal layer, the metal layer may be locally heated. In other words, in the step of heating the metal layer, the metal layer may be heated while restraining increase of temperature at a region adjacent to the metal layer.

In this way, even in the case where the backside electrode is formed after forming a wire made of a metal having a relatively low melting point such as Al (aluminum), damage on the wire can be restrained.

In the method for manufacturing the semiconductor device, in the step of heating the metal layer, the metal layer may be locally heated by irradiating the metal layer with laser. The local heating for the metal layer can be readily implemented by employing the laser irradiation, which provides an irradiation range that can be readily limited.

As apparent from the description above, according to the method for manufacturing the semiconductor device in the present invention, there can be provided a method for manufacturing a semiconductor device, which allows for sufficient reduction of on-resistance.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a flowchart schematically showing a method for manufacturing a semiconductor device.

FIG. 2 is a schematic cross sectional view for illustrating the method for manufacturing the semiconductor device.

FIG. 3 is a schematic cross sectional view for illustrating the method for manufacturing the semiconductor device.

FIG. 4 is a schematic cross sectional view for illustrating the method for manufacturing the semiconductor device.

FIG. 5 is a schematic cross sectional view for illustrating the method for manufacturing the semiconductor device.

FIG. 6 is a schematic cross sectional view for illustrating the method for manufacturing the semiconductor device.

FIG. 7 is a schematic cross sectional view for illustrating the method for manufacturing the semiconductor device.

FIG. 8 is a schematic cross sectional view for illustrating the method for manufacturing the semiconductor device.

FIG. 9 is a schematic cross sectional view for illustrating the method for manufacturing the semiconductor device.

FIG. 10 is a schematic cross sectional view for illustrating the method for manufacturing the semiconductor device.

### DESCRIPTION OF THE PREFERRED EMBODIMENTS

The following describes an embodiment of the present invention with reference to figures. It should be noted that in the below-mentioned figures, the same or corresponding portions are given the same reference characters and are not described repeatedly. Further, in the present specification, an individual orientation is represented by [ ], a group orientation is represented by < >, and an individual plane is represented by ( ), and a group plane is represented by { }. In addition, a negative index is supposed to be crystallographically indicated by putting “-” (bar) above a numeral, but is indicated by putting the negative sign before the numeral in the present specification.

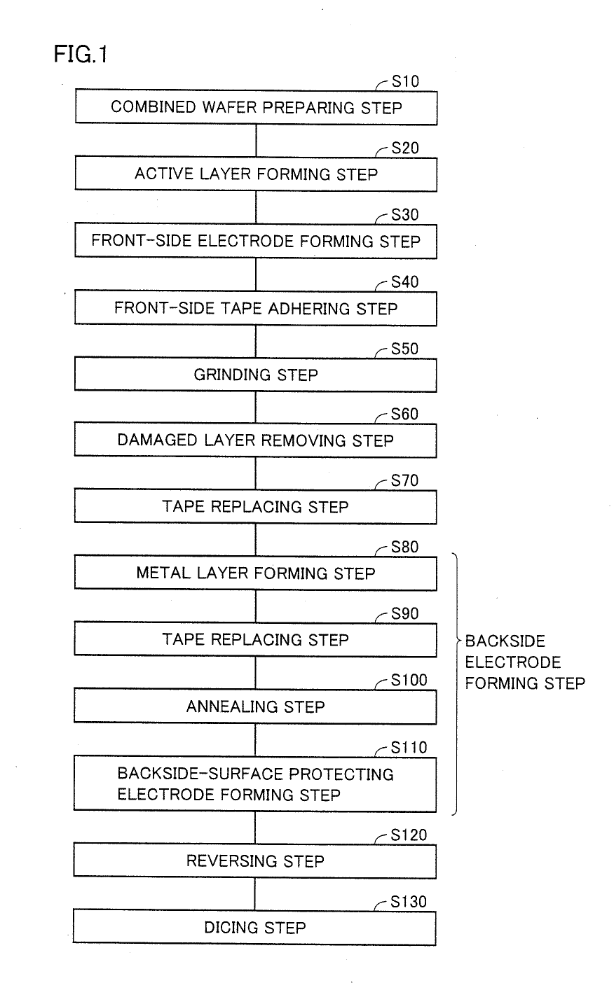

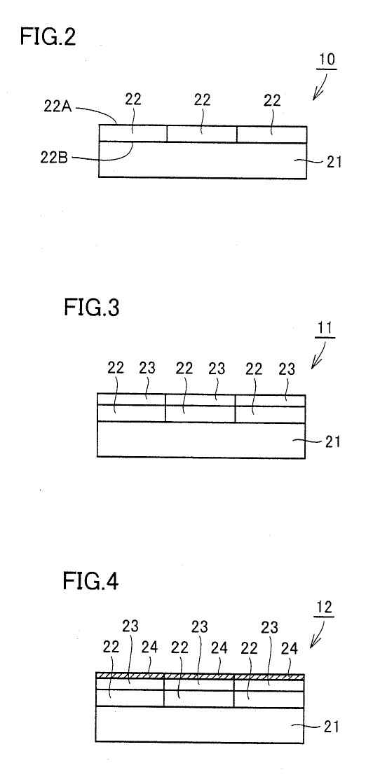

Referring to FIG. 1, in a method for manufacturing a semiconductor device in one embodiment of the present invention, a combined wafer preparing step is first performed as a step (S10). In this step (S10), referring to FIG. 2, a combined wafer 10 is prepared in which a plurality of SiC substrates 22 each made of silicon carbide single-crystal are arranged side by side when viewed in a plan view and second main surfaces 22B of the plurality of SiC substrates 22 opposite to first main surfaces 22A thereof are connected to each other by a supporting layer 21. An exemplary SiC substrate 22 employable is a substrate made of hexagonal silicon carbide such as 4H—SiC. Meanwhile, for supporting layer 21, a substrate made of a metal may be employed. However, it is preferable to employ a substrate made of silicon carbide in order to suppress warpage resulting from a difference in physical property such as thermal expansion coefficient. As the silicon carbide constituting supporting layer 21, polycrystal silicon carbide or amorphous silicon carbide may be employed, but it is more preferable to employ single-crystal silicon carbide of hexagonal silicon carbide such as 4H—SiC.

Further, first main surface 22A of SiC substrate 22 has an off angle of not less than 50° and not more than 65° relative to the {0001} plane. More specifically, for example, each of first main surface 22A and second main surface 22B corresponds to a plane having an angle of 5° or smaller relative to the {03-38} plane. First main surface 22A corresponds to a plane at the carbon plane side in the silicon carbide single-crystal, whereas second main surface 22B corresponds to a plane at the silicon plane side therein.

Next, an active layer forming step is performed as a step (S20). In this step (S20), referring to FIG. 2 and FIG. 3, an active layer 23 is formed on each of first main surfaces 22A of SiC substrates 22 of combined wafer 10, thereby fabricating a first intermediate wafer 11. Specifically, for example, an epitaxial growth layer made of silicon carbide is formed on each of SiC substrates 22. Thereafter, regions having impurities introduced therein by means of, for example, ion implantation are formed in the epitaxial growth layer. Thereafter, activation annealing is performed to form a plurality of regions having different conductivity types in the epitaxial growth layer. Accordingly, active layer 23 contributing to a predetermined operation of the semiconductor device is obtained.

Next, as a step (S30), a front-side electrode forming step is performed. In this step (S30), referring to FIG. 3 and FIG. 4, a front-side electrode 24 is formed on active layer 23 of first intermediate wafer 11, thereby fabricating a second intermediate wafer 12. Specifically, examples of such an electrode formed on active layer 23 include: a gate electrode made of polysilicon and disposed on a gate insulating film provided on active layer 23; a source electrode made of nickel and disposed in contact with active layer 23; and a source wire connected to the source electrode and made of Al or the like.

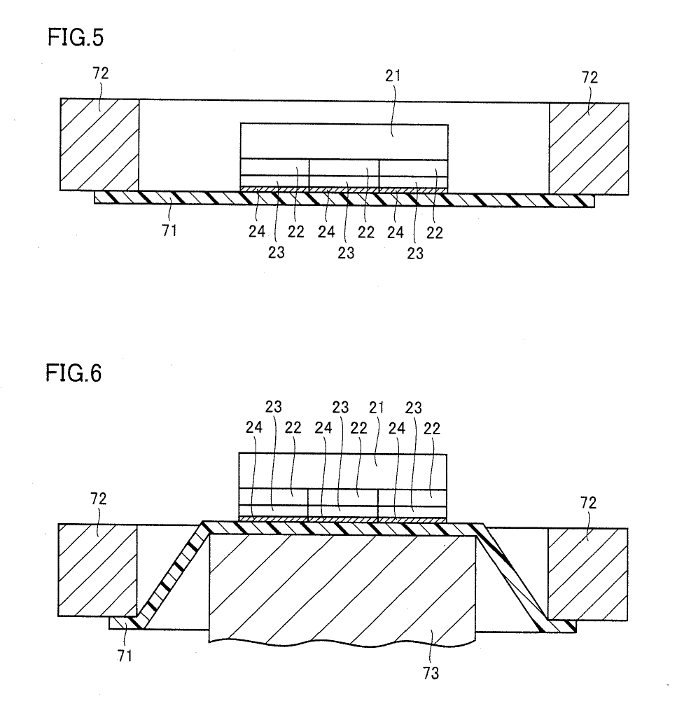

Next, a front-side tape adhering step is performed as a step (S40). In this step (S40), an adhesive tape is adhered to the main surface of second intermediate wafer 12 on which front-side electrode 24 is formed, whereby the plurality of SiC substrates 22 are supported by the adhesive tape with SiC substrates 22 being arranged side by side when viewed in a plan view. Specifically, referring to FIG. 5, first, an annular ring frame 72 made of a metal is prepared. Next, adhesive tape 71 is set and held at ring frame 72 to close a hole extending through ring frame 72. With adhesive tape 71 being thus held by ring frame 72, adhesive tape 71 is securely provided with surface smoothness. Next, second intermediate wafer 12 is put on adhesive tape 71 for adhesion such that its main surface having front-side electrode 24 formed thereon comes into contact with the adhesive surface of adhesive tape 71. As a result, second intermediate wafer 12, which is thus adhered to adhesive tape 71, is held at a location surrounded by the inner circumference surface of ring frame 72. It should be noted that adhesive tapes having various configurations can be employed as adhesive tape 71, and an exemplary, usable adhesive tape is one which employs polyester for a base material thereof, employs an acrylic adhesive agent for a adhesive agent thereof, and employs polyester for a separator thereof. Further, adhesive tape 71 preferably has a thickness of 150 μm or smaller.

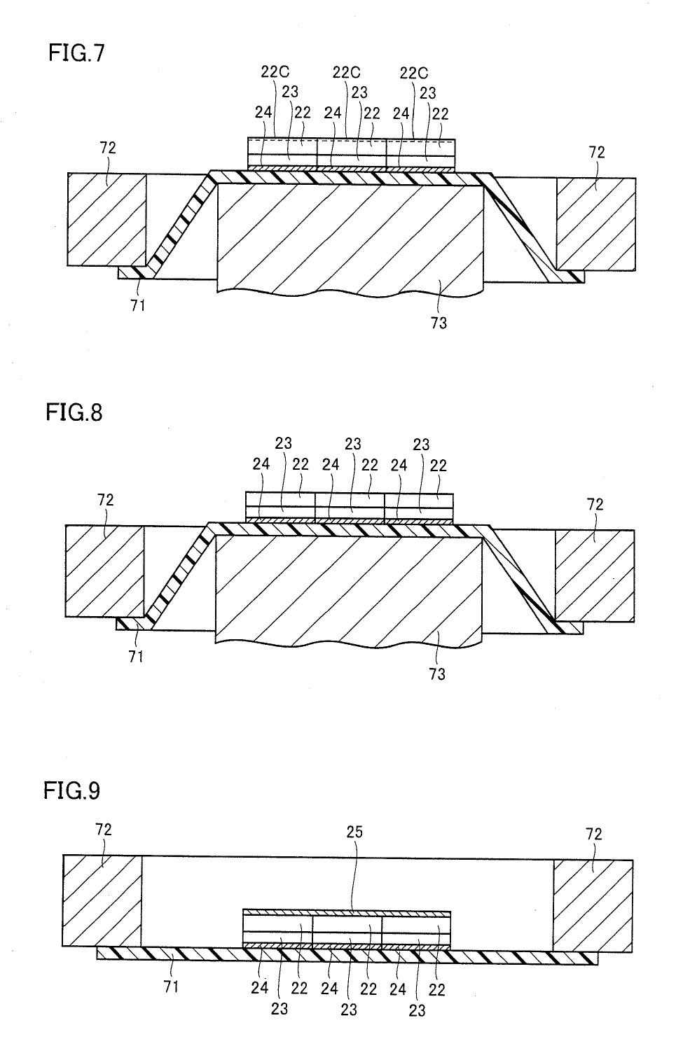

Next, a grinding step is performed as a step (S50). In this step (S50), supporting layer 21 is removed by means of a grinding process while the plurality of SiC substrates 22 of second intermediate wafer 12 are supported by adhesive tape 71 with SiC substrates 22 being arranged side by side when viewed in a plan view. Specifically, referring to FIG. 6, the main surface of adhesive tape 71 opposite to its side holding second intermediate wafer 12 is pressed by a pressing member 73 in the axial direction of ring frame 72. Accordingly, adhesive tape 71 is elastically deformed, whereby at least supporting layer 21 of second intermediate wafer 12 held by adhesive tape 71 is deviated from the location surrounded by the inner circumference surface of ring frame 72. Then, supporting layer 21 is pressed against a grinding surface of a grinding device such as a grinder (not shown), thereby grinding supporting layer 21. Accordingly, supporting layer 21 is removed as shown in FIG. 7. In doing so, a portion of each of SiC substrates 22 may be removed by the grinding in order to securely remove supporting layer 21.

Next, as a step (S60), a damaged layer removing step is performed. In this step (S60), referring to FIG. 7 and FIG. 8, a damaged layer 22C formed in SiC substrate 22 in step (S50) is removed. Damaged layer 22C can be removed by means of, for example, dry polishing or dry etching. The dry polishing can be performed using, for example, oxidation metal abrasive grains. Accordingly, damaged layer 22C can be removed while restraining new damage on SiC substrate 22.

Next, as a step (S70), a tape replacing step is performed. In this step, adhesive tape 71 is replaced after completing the steps up to step (S60) by finishing the pressing of adhesive tape 71 by pressing member 73. This step (S70) is not an essential step in the method for manufacturing the semiconductor device in the present invention, but a problem resulting from damage on adhesive tape 71 can be avoided in advance by replacing adhesive tape 71, which might be damaged in steps (S50) and (S60) as a result of the elastic deformation or the like.

Next, referring to FIG. 1, a backside electrode forming step is performed. In this step, a backside electrode is formed on the main surfaces of SiC substrates 22 exposed by the removal of supporting layer 21 in step (S50) and removal of damaged layer 22C in step (S60). This backside electrode forming step includes a metal layer forming step performed as a step (S80), and a tape replacing step performed as a step (S90), an annealing step performed as a step (S100), and a backside-surface protecting electrode forming step performed as a step (S110). In step (S80), referring to FIG. 9, a metal layer made of a metal such as nickel is formed on the main surfaces of SiC substrates 22 opposite to the side on which active layer 23 is formed. This metal layer can be formed using sputtering, for example. On this occasion, adhesive tape 71, ring frame 72, and the wafer may be cooled using a cooling structure (not shown) as required.

Next, in step (S90), adhesive tape 71 is replaced after completion of step (S80). This step (S90) is not an essential step in the method for manufacturing the semiconductor device in the present invention, but a problem resulting from damage or the like on adhesive tape 71 can be avoided in advance by replacing adhesive tape 71, which might be damaged in the processes up to step (S80), or by replacing it with another adhesive tape 71 suitable for the below-described step (S100).

Next, in step (S100), the metal layer formed in step (S80) is heated. Specifically, referring to FIG. 9, when the metal layer made of, for example, nickel is formed in step (S80), regions of the metal layer in contact with at least SiC substrates 22 are silicided by the heating in step (S100), thereby obtaining a backside contact electrode making ohmic contact with SiC substrates 22.

Next, in step (S110), on the backside contact electrode formed through steps (S80) to (S100), a backside-surface protecting electrode made of, for example, Al or the like is formed. This backside-surface protecting electrode can be formed by means of, for example, a deposition method. With the above-described steps (S80) to (S110), backside electrode 25 is formed.

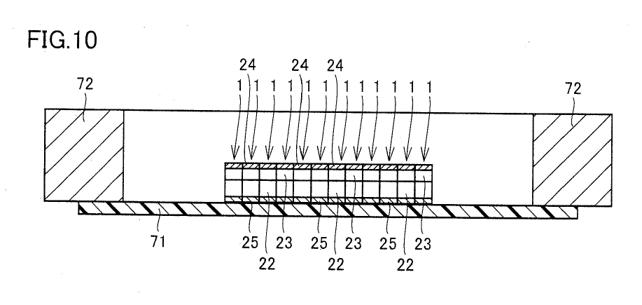

Next, a reversing step is performed as a step (S120). In this step (S120), referring to FIG. 9 and FIG. 10, an adhesive tape is adhered to the side on which backside electrode 25 is formed, and the adhesive tape at the front-side electrode 24 side is removed. Accordingly, the plurality of SiC substrates 22 are supported by adhesive tape 71 with SiC substrates 22 being arranged side by side when viewed in a plan view. Accordingly, as shown in FIG. 10, the wafer is held by adhesive tape 71 with the wafer being reversed from the state in step (S110). As a result, the front-side surface of the wafer can be observed, whereby the next step (S130) can be readily performed.

Next, as step (S130), a dicing step is performed. In this step (S130), referring to FIG. 10, SiC substrates 22 supported by adhesive tape 71 at the backside electrode 25 side are cut (diced) in the thickness direction thereof with SiC substrates 22 being arranged side by side when viewed in a plan view. In this way, a plurality of semiconductor devices 1 are obtained. It should be noted that this cutting may be performed by means of laser dicing, scribing, or the like. With the above-described procedure, the method for manufacturing semiconductor device 1 in the present embodiment is completed.

Here, in the method for manufacturing semiconductor device 1 in the present embodiment, the other main surface opposite to one main surface (first main surface 22A) having an off angle of not less than 50° and not more than 65° relative to the {0001} plane is grinded, thereafter damaged layer 22C formed by the grinding is removed, and then backside electrode 25 is formed. Hence, even when defects are formed up to a deep region, the region including the defects are removed before forming backside electrode 25, thereby achieving a small contact resistance between SiC substrate 22 and backside electrode 25. Accordingly, the on-resistance of semiconductor device 1 is sufficiently reduced.

Further, in the method for manufacturing semiconductor device 1 in the present embodiment, combined wafer 10 is prepared which has the plurality of SiC substrates 22 each made of single-crystal silicon carbide, arranged side by side when viewed in a plan view, and each having one main surface connected by supporting layer 21 (see FIG. 2). Such a combined wafer 10 can be handled as a silicon carbide substrate having excellent crystallinity and having a large diameter. Use of combined wafer 10 allows for efficient manufacturing of semiconductor devices 1.

Further, in the method for manufacturing semiconductor device 1 in the present embodiment, supporting layer 21 is removed while second intermediate wafer 12 is supported using adhesive tape 71. Further, the plurality of SiC substrates 22 are kept on being supported by adhesive tape 71 with SiC substrates 22 being arranged side by side when viewed in a plan view until SiC substrates 22 are cut to obtain the plurality of semiconductor devices 1 in the subsequent step (S130). As a result, the plurality of SiC substrates 22 are avoided from being separated from one another, thereby allowing for efficient manufacturing of semiconductor devices 1.

Further, the wafer (SiC substrates 22) has been thinned due to the removal of supporting layer 21 to thereby have decreased hardness. However, in the above-described manufacturing method, the wafer is reinforced by adhesive tape 71 while being held, thereby restraining damage on the wafer during the process. Further, the wafer having been thinned due to the removal of supporting layer 21 and adhered to adhesive tape 71 held by ring frame 72 is transferred between devices for performing the above-described steps. Accordingly, the wafer can be smoothly transferred between the devices.

Thus, in the method for manufacturing the semiconductor device in the present embodiment, the process is simple and manufacturing efficiency is excellent. Hence, the manufacturing method is suitable for mass production of semiconductor devices.

Here, the replacement of adhesive tape 71 in each of step (S70) and step (S90) can be implemented as follows. First, the plurality of SiC substrates 22 arranged side by side when viewed in a plan view are held by an adsorbing member. Thereafter, the adhesive tape is detached and then a new adhesive tape is adhered. Thereafter, the adsorption by the adsorbing member is terminated.

Further, in the above-described step (S100), front-side electrode 24 may have a temperature maintained at 180° C. or smaller. Accordingly, the adhesive tape does not need to have a high heat resistance, thereby providing a wider range of choices for a material for the adhesive tape. Hence, a general resin tape can be employed as the above-described adhesive tape, for example.

Further, in step (S100), it is preferable to locally heat the metal layer. This achieves suppressed damage on the wire formed in step (S30), adhesive tape 71, and the like. This local heating may be attained by laser irradiation for the metal layer. In this way, the local heating can be readily done.

Further, the above-described laser preferably has a wavelength of 355 nm. In this way, even in the case where the metal layer has a defect portion such as a pinhole, the metal layer can be appropriately heated while suppressing damage on front-side electrodes 24, a surrounding device, and the like.

Further, for the adhesive tape of the present embodiment, there may be used an adhesive tape (UV tape) having adhesive force to be reduced when irradiated with ultraviolet rays, or an adhesive tape having adhesive force to be reduced when being heated. By thus employing the adhesive tape having its adhesive force which can be readily reduced as required, the above-described manufacturing process can be performed smoothly.

It should be noted that the semiconductor device that can be manufactured in accordance with the method for manufacturing the semiconductor device in the present invention is not particularly limited as long as it is a semiconductor device having a front-side electrode and a backside electrode. The manufacturing method of the present invention can be used to manufacture a MOSFET (Metal Oxide Semiconductor Field Effect Transistor), an IGBT (Insulated Gate Bipolar Transistor), a JFET (Junction Field Effect Transistor), a diode, or the like.

Further, it has been illustrated that combined wafer 10 is prepared as the substrate in the above-described embodiment, but when manufacturing the semiconductor device, a substrate made of single-crystal silicon carbide may be prepared and the adhesive tape may not be used.

### EXAMPLE

An experiment was conducted to inspect a relation between removal of a damaged layer formed by grinding the backside surface of a substrate and a contact resistance between the substrate and an electrode. The experiment was conducted in the following procedure.

Prepared first were a silicon carbide substrate having a carrier density N_{d} of 1×10¹⁸ cm⁻³ and having a main surface corresponding to a plane with a plane orientation of (000-1); and silicon carbide substrates each having a carrier density N_{d} of 1×10¹⁸ cm⁻³ and each having a main surface corresponding to a plane with a plane orientation of (03-38). Then, they were grinded using a grinding stone of #2000 and/or a grinding stone of #7000, and part of the substrates were then subjected to dry etching or dry polishing in order to remove damaged layers therefrom. Thereafter, on each of the grinded main surfaces, a TLM (Transmission Line Model) pattern was formed using Ni (nickel). Then, they were heated to 1000° C. using lamp annealing equipment so as to perform annealing for alloying, thereby forming an electrode. Then, a current was permitted to flow therein in the lateral direction to evaluate a contact resistance of the electrode based on I-V characteristics. It should be noted that in the TLM evaluation, a general evaluation method was employed such as a method described in IEEE Electron Device Letters, Vol. 3, p. 111, 1982, for example. A result of the experiment is shown in Table 1.

TABLE 1

| | Plane Orientation | | | |
|---|---|---|---|---|
| | (000-1) | (03-38) | (03-38) | (03-38) |
| Method for | Grinding | Grinding | Grinding | Grinding |
| Processing the | with #2000 | with #2000 | with #2000 | with #2000 |
| Backside | ↓ | ↓ | ↓ | ↓ |
| Surface | Grinding | Grinding | Grinding | Dry |
| | with #7000 | with #7000 | with #7000 | Polishing |
| | | | ↓ | |
| | | | Dry Etching | |
| Characteristics | 5 × 10⁻⁴ | 5 × 10⁻³ | 5 × 10⁻⁴ | 5 × 10⁻⁴ |
| of Electrode | Ωcm² or | Ωcm² or | Ωcm² or | Ωcm² or |
| (Contact | smaller | greater | smaller | smaller |
| Resistance) | | | | |

Referring to Table 1, the substrate having its main surface with a plane orientation of (000-1) had a sufficiently low contact resistance even in the case where the damaged layer was not removed after the grinding. This is presumably because defects tend to be formed and expand along the {0001} plane of the silicon carbide and therefore were not formed to reach a region deep from the surface thereof as described above. On the other hand, the substrate having its main surface with a plane orientation of (03-38) and not having been subjected to the removal of the damaged layer after the grinding had a high contact resistance. In contrast, the substrates having their main surfaces with a plane orientation of (03-38) and having been subjected to the removal of the damaged layer after the grinding had a sufficiently low contact resistance.

From the result of experiment, it was confirmed that the contact resistance between the substrate and the electrode can be reduced by the method for manufacturing the semiconductor device in the present invention in which the damaged layer is removed after the grinding and then the electrode (backside electrode) is formed.

The method for manufacturing the semiconductor device in the present invention can be particularly advantageously applied to a method for manufacturing a semiconductor device required to achieve reduced on-resistance.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method for manufacturing a semiconductor device, comprising the steps of:
preparing a substrate having a region that at least includes one main surface thereof and that is made of single-crystal silicon carbide;
forming an active layer on said one main surface;
grinding a region including the other main surface of said substrate opposite to said one main surface;
removing a damaged layer formed in the step of grinding said region including the other main surface; and
forming a backside electrode in contact with the main surface exposed by the removal of said damaged layer,
said one main surface having an off angle of not less than 50° and not more than 65° relative to a {0001} plane.

2. The method for manufacturing the semiconductor device according to claim 1, wherein in the step of removing said damaged layer, said damaged layer is removed by dry polishing.

3. The method for manufacturing the semiconductor device according to claim 1, wherein in the step of removing said damaged layer, said damaged layer is removed by dry etching.

4. The method for manufacturing the semiconductor device according to claim 1, wherein:
in the step of preparing said substrate, a combined wafer is prepared in which a plurality of SiC substrates each made of single-crystal silicon carbide are arranged side by side when viewed in a plan view, said plurality of SiC substrates having first main surfaces that serve as said one main surface and having second main surfaces opposite to said first main surfaces and connected to each other by a supporting layer, and
in the step of grinding said region including the other main surface, said supporting layer is removed.

5. The method for manufacturing the semiconductor device according to claim 4, further comprising the steps of:
forming a front-side electrode on said active layer; and
adhering an adhesive tape at a side thereof on which said front-side electrode is formed, so as to support said plurality of SiC substrates using the adhesive tape with said plurality of SiC substrates being arranged side by side when viewed in a plan view,
in the step of grinding said region including the other main surface, said supporting layer being removed while using the adhesive tape to support said plurality of SiC substrates with said plurality of SiC substrates being arranged side by side when viewed in a plan view, the method further comprising the steps of:
adhering an adhesive tape at a side thereof on which said backside electrode is formed, and removing the adhesive tape at the side thereof on which said front-side electrode is formed, so as to support said plurality of SiC substrates using the adhesive tape with said plurality of SiC substrates being arranged side by side when viewed in a plan view; and
obtaining a plurality of semiconductor devices by cutting said SiC substrates in a thickness direction thereof with said plurality of SiC substrates being supported by side by side when viewed in a plan view using the adhesive tape at the side thereof on which said backside electrode is formed.

6. The method for manufacturing the semiconductor device according to claim 1, wherein:
the step of forming said backside electrode includes the steps of
forming a metal layer in contact with the main surface exposed by the removal of said damaged layer, and
heating said metal layer.

7. The method for manufacturing the semiconductor device according to claim 6, wherein in the step of heating said metal layer, said metal layer is locally heated.

8. The method for manufacturing the semiconductor device according to claim 7, wherein in the step of heating said metal layer, said metal layer is locally heated by irradiating said metal layer with laser.
